(19) United States
(12) Patent Application Publication
(10) Pub. No.: US 2025/0278005 A1
(43) Pub. Date: Sep. 4, 2025

(54) LIGHT CONTROL PANEL AND DISPLAY DEVICE INCLUDING THE SAME

(71) Applicant: LG Display Co., Ltd., Seoul (KR)

(72) Inventors: Heejong SHIN, Goyang-si (KR); Youngki SONG, Paju-si (KR); Kyoung-Sang YOON, Paju-si (KR)

(21) Appl. No.: 18/946,539

(22) Filed: Nov. 13, 2024

(30) Foreign Application Priority Data
Feb. 29, 2024 (KR) 10-2024-0030229

(51) Int. Cl. G02F 1/1679; G02F 1/1676; G02F 1/1677

(52) U.S. Cl. CPC G02F 1/1679; G02F 1/1676; G02F 1/1677

(57) ABSTRACT

The present specification relates to a light control panel and a transparent display device including the same. A light control panel according to the present disclosure includes a first electrode, a second electrode disposed on the first electrode while facing the first electrode, a dielectric layer provided between the first electrode and the second electrode and including a plurality of dielectric patterns disposed between a plurality of grooves, and a plurality of spacers spaced apart from the plurality of dielectric patterns and further protruding toward the second electrode than the plurality of dielectric patterns, an ink layer disposed in a space between the dielectric layer and the second electrode and including charged particles, a light-blocking pattern disposed on the plurality of spacers, and a bonding layer disposed between the ink layer and the second electrode, in which the light-blocking pattern is disposed to be in contact with the bonding layer.

### CROSS-REFERENCE TO RELATED APPLICATIONS

This application claims the priority of Korean Patent Application No. 10-2024-0030229 filed on Feb. 29, 2024, in the Korean Intellectual Property Office, the disclosure of which is incorporated herein by reference.

### BACKGROUND

### Technical Field

The present specification relates to a light control panel and a display device including the same, and more particularly, to a light control panel, which is capable of improving image quality properties by increasing a shield factor in a light-blocking mode of a display device, and a display device including the same.

### Description of the Related Art

Display devices, which visually display electrical information signals, are being rapidly developed in accordance with the entry into the information era. Various studies are being continuously conducted to develop a variety of display devices which are thin and lightweight, consume low power, and have improved performance.

As the representative display devices, there may be a liquid crystal display device (LCD), a field emission display device (FED), an electrowetting display device (EWD), an organic light-emitting display device (OLED), and the like.

An electroluminescent display device, as the representative organic light-emitting display device, refers to a display device that autonomously emits light. Unlike a liquid crystal display device, the electroluminescent display device does not require a separate light source and thus may be manufactured as a lightweight, thin display device. In addition, the electroluminescent display device is advantageous in terms of power consumption because the electroluminescent display device operates at a low voltage. Further, the electroluminescent display device is expected to be adopted in various fields because the electroluminescent display device is also excellent in implementation of colors, response speeds, viewing angles, and contrast ratios (CRs).

### BRIEF SUMMARY

Various embodiments of the present specification provide a light control panel, which is capable of freely switching between a light-blocking mode and a transmissive mode in response to a user's needs, and a display device including the same.

Various embodiments of the present specification provide a light control panel, which is capable of improving image quality properties by increasing a shield factor in a light-blocking mode of a display device, and a display device including the same.

Technical benefits of the present disclosure are not limited to the above-mentioned benefits, and other benefits, which are not mentioned above, can be clearly understood by those skilled in the art from the following descriptions.

A light control panel according to an embodiment of the present disclosure includes: a first electrode; a second electrode disposed on the first electrode while facing the first electrode; a dielectric layer provided between the first electrode and the second electrode and including a plurality of dielectric patterns disposed between a plurality of grooves, and a plurality of spacers spaced apart from the plurality of dielectric patterns and further protruding toward the second electrode than the plurality of dielectric patterns; an ink layer disposed in a space between the dielectric layer and the second electrode and including charged particles; a light-blocking pattern disposed on the plurality of spacers; and a bonding layer disposed between the ink layer and the second electrode, in which the light-blocking pattern is disposed to be in contact with the bonding layer.

A display device according to another embodiment of the present disclosure includes: a transparent display panel including a transmissive area configured to transmit external light, and a non-transmissive area in which a plurality of pixels is disposed; and a light control panel positioned below the display panel, in which the light control panel includes: a first electrode; a second electrode disposed on the first electrode while facing the first electrode; a dielectric layer provided between the first electrode and the second electrode and including a plurality of dielectric patterns disposed between a plurality of grooves, and a plurality of spacers spaced apart from the plurality of dielectric patterns and further protruding toward the second electrode than the plurality of dielectric patterns; an ink layer disposed in a space between the dielectric layer and the second electrode and including charged particles; a light-blocking pattern disposed on the plurality of spacers; and a bonding layer disposed between the ink layer and the second electrode, in which the light-blocking pattern is disposed to be in contact with the bonding layer.

Other detailed matters of the exemplary embodiments are included in the detailed description and the drawings.

According to the light control panel and the display device including the same according to the embodiment of the present specification, it is possible to selectively implement the light-blocking mode and the transmissive mode.

According to the light control panel and the display device including the same according to the embodiment of the present specification, the user may clearly recognize an object and background positioned on the rear surface of the display device in the transmissive mode, and the user may be provided with an image with a high contrast ratio in the light-blocking mode by inhibiting the external light from penetrating into the display device.

According to the light control panel and the display device including the same according to the embodiment of the present specification, the plurality of dielectric patterns, the plurality of spacers, and the plurality of grooves are simultaneously formed by the imprinting process, such that the manufacturing process costs may be reduced, the process may be simplified, the manufacturing process time may be shortened, and the production energy may be reduced.

According to the light control panel and the display device including the same according to the embodiment of the present specification, the manufacturing process may be optimized, such that the occurrence of greenhouse gas, which may be generated by the manufacturing process, may be reduced, thereby implementing ESG (environment/social/governance).

According to the light control panel and the display device according to the embodiment of the present specification, the light-blocking pattern is disposed on the plurality of spacers, such that the shield factor in the light-blocking mode of the display device may be increased, which may improve the image quality properties.

The effects according to the present disclosure are not limited to the contents exemplified above, and more various effects are included in the present specification.

### BRIEF DESCRIPTION OF THE SEVERAL VIEWS OF THE DRAWINGS

The above and other aspects, features and other advantages of the present disclosure will be more clearly understood from the following detailed description taken in conjunction with the accompanying drawings, in which:

FIG. 1 is a perspective view of a display device according to an embodiment of the present specification;

FIG. 2 is a top plan view of the display panel according to the embodiment of the present specification;

FIG. 3 is a schematic top plan view illustrating a plurality of pixels according to the embodiment of the present specification;

FIG. 4 is a circuit diagram of a subpixel in FIG. 3;

FIG. 5 is a cross-sectional view taken along line V-V′ in FIG. 3;

FIG. 6A is a cross-sectional view illustrating a light control panel according to the embodiment of the present specification;

FIG. 6B is a cross-sectional view for explaining a method of implementing a transmissive mode in the light control panel according to the embodiment of the present specification;

FIGS. 7A to 7D is an image illustrating a printed state of a light-blocking pattern of the light control panel according to the embodiment of the present specification;

FIG. 8 is an image illustrating printing width uniformity of the light-blocking pattern of the light control panel according to the embodiment of the present specification; and

FIGS. 9A and 9B are front-of-screen (FOS) images illustrating external appearance states in the light-blocking modes of the display devices according to the embodiment of the present specification and a comparative example.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, dimensions (e.g., length, width, height, thickness, radius, diameter, area, etc.), ratios, angles, numbers, and the like illustrated in the accompanying drawings for describing the exemplary embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

The features of various embodiments of the present disclosure can be partially or entirely adhered to or combined with each other and can be interlocked and operated in technically various ways, and the embodiments can be carried out independently of or in association with each other.

Hereinafter, various exemplary embodiments of the present disclosure will be described in detail with reference to the accompanying drawings.

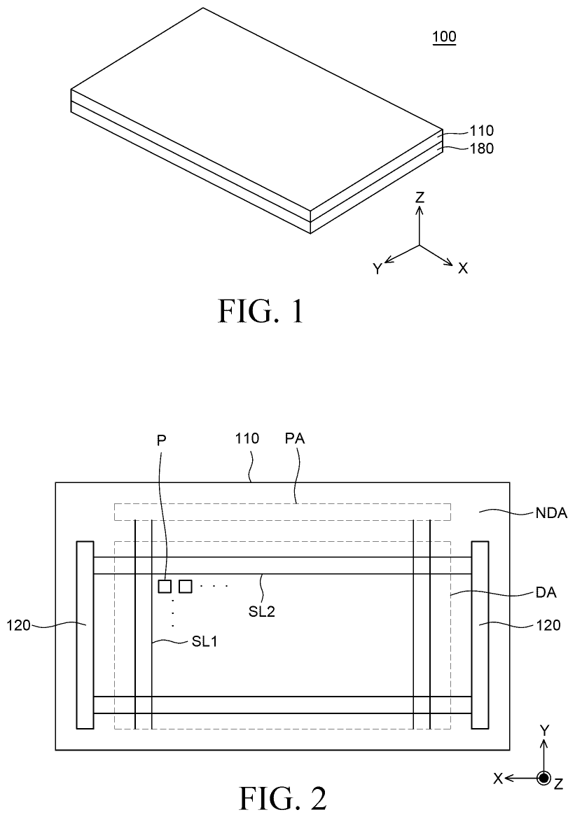

FIG. 1 is a perspective view of a display device according to an embodiment of the present specification.

In FIG. 1, an X-axis represents a direction parallel to a gate line, a Y-axis represents a direction parallel to a data line, and a Z-axis represents a height direction of a display device.

The description will be focused on a configuration in which a display device 100 according to an embodiment of the present specification is implemented as an organic light-emitting display device. However, the display device may also be implemented as a liquid crystal display device, a plasma display panel (PDP) device, a quantum dot light emitting display (QLED) device, or an electrophoresis display device.

With reference to FIG. 1, the display device 100 according to the embodiment of the present specification includes a display panel 110 and a light control panel 180.

The display device 100 according to the embodiment of the present specification may be the display device 100 in which at least a partial area of a screen of the display device 100, which is visually recognized by a viewer, is transparent. For example, the display device 100 may also be referred to as a transparent display device. The display device 100 according to the embodiment of the present specification may be the display device 100 having transparency at a level at which a user may at least recognize an object on a rear surface of the display device 100.

The display panel 110 has a plurality of pixels P and displays images. A transmissive area may be provided in at least a partial area of the display panel 110 and transmit most parts of light entering from the outside. The display panel 110 may have the transmissive area provided between the plurality of pixels. An object or background positioned outside the display panel 110 may be visible through the transmissive areas of the display panel 110.

The light control panel 180 may be disposed on at least one surface of the display panel 110 and control light entering the display panel 110. The light control panel 180 may include an ink layer containing charged particles configured to be moved by an electric field. The light control panel 180 may implement a light-blocking mode and a transmissive mode by controlling a motion of the ink layer containing the charged particles. As a voltage is applied to the ink layer containing the charged particles, the mode may switch from the light-blocking mode to the transmissive mode or switch from the transmissive mode to the light-blocking mode. The light control panel 180 may block the incident light in the light-blocking mode and transmit the incident light in the transmissive mode.

The light control panel 180 may be disposed in a direction opposite to a direction in which the display panel 110 emits light. For example, as illustrated in FIG. 1, in case that the display panel 110 is a top-emission type, the light control panel 180 may be disposed below the display panel 110. As another example, in case that the display panel 110 is a bottom-emission type, the light control panel 180 may be disposed above the display panel 110.

Although not illustrated, the light control panel 180 may be bonded to one surface of the display panel 110 by using a bonding layer. The bonding layer (not illustrated) may be a transparent bonding film, such as an optically clear adhesive (OCA) or a transparent bonding agent such as an optically clear resin (OCR).

FIG. 1 illustrates that the light control panel 180 is disposed on one surface exposed to the outside of the display panel 110. However, the present specification is not necessarily limited thereto. The light control panel 180 may be disposed in the display panel 110. In this case, the light control panel 180 may be disposed on a top surface of any one layer among a plurality of layers provided on the display panel 110. For example, the light control panel 180 may be provided between a substrate and a transistor of the display panel 110. In this case, the light control panel 180 may not have a separate substrate.

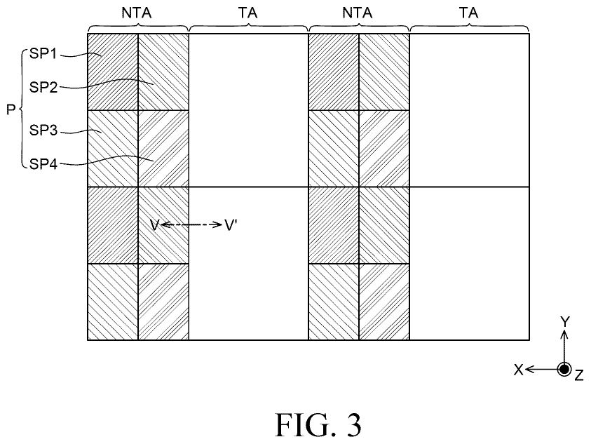

Hereinafter, the display panel 110 will be described more specifically with reference to FIGS. 2 to 5.

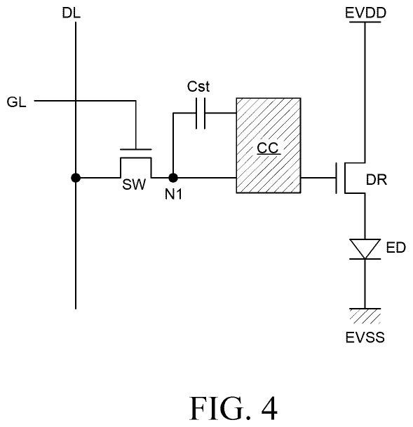

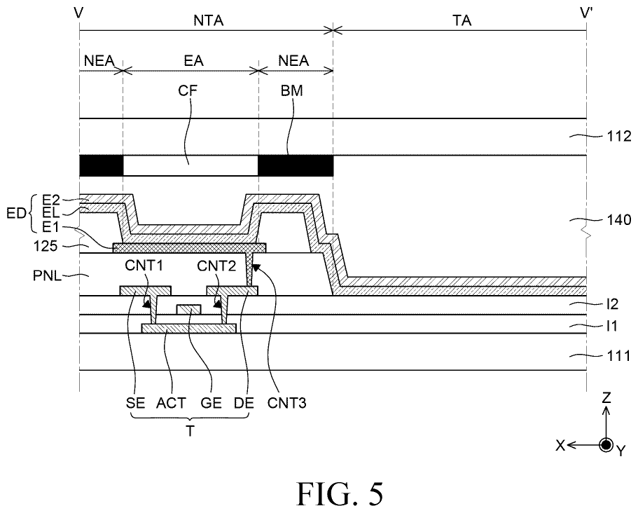

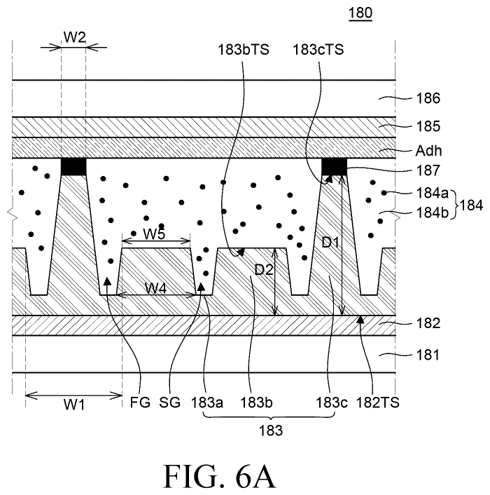

FIG. 2 is a top plan view of the display panel according to the embodiment of the present specification. FIG. 3 is a schematic top plan view illustrating the plurality of pixels according to the embodiment of the present specification. FIG. 4 is a circuit diagram of a subpixel in FIG. 3. FIG. 5 is a cross-sectional view taken along line V-V′ in FIG. 3.

In FIG. 2, the X-axis represents the direction parallel to the gate line, the Y-axis represents the direction parallel to the data line, and the Z-axis represents the height direction of the display device.

With reference to FIGS. 2 to 5, the display panel 110 according to the embodiment of the present specification may be divided into a display area DA in which the pixels P are formed to display images, and a non-display area NDA in which no image is displayed.

First signal lines SL1, second signal lines SL2, and the pixels may be provided in the display area DA. A pad area PA, in which pads are disposed, and at least one scan driver 120 may be provided in the non-display area NDA.

The first signal lines SL1 and the pixels P may be disposed in the display area DA and extend in a first direction (e.g., the Y-axis direction). For example, the first signal lines SL1 may be data lines. However, the present specification is not necessarily limited thereto. The first signal lines SL1 may include at least one of a pixel power line, a common power line, and a reference line.

The second signal lines SL2 may extend in a second direction (e.g., the X-axis direction) in the display area DA and intersect the first signal lines SL1 in the display area DA. For example, the second signal lines SL2 may be scan lines. However, the present specification is not necessarily limited thereto.

The scan driver 120 is connected to the scan line and supplies scan signals. The scan driver 120 may be formed in a GIP (gate driver in panel) manner or a TAB (tape automated bonding) manner in the non-display area NDA outside one side or two opposite sides of the display area DA of the display panel 110.

As illustrated in FIG. 3, the display area DA includes transmissive areas TA and non-transmissive areas NTA. The transmissive area TA is an area that transmits most parts of the light entering from the outside. The non-transmissive area NTA is an area that does not transmit most parts of the light entering from the outside. For example, the transmissive area TA may be an area having light transmittance of more than α%, and the non-transmissive area NTA may be an area having light transmittance of less than β%. In this case, α is a value larger than β. An object or background positioned on the rear surface of the display device 100 may be visible through the transmissive areas TA of the display panel 110 of the display device 100.

The non-transmissive area NTA includes a light-emitting area EA having the plurality of pixels P and configured to emit light. The plurality of pixels P may each include a first subpixel SP1, a second subpixel SP2, a third subpixel SP3, and a fourth subpixel SP4. The first subpixel SP1 may include a first light-emitting area EA configured to emit light with a first color, and the second subpixel SP2 may include a second light-emitting area EA configured to emit light with a second color. The third subpixel SP3 may include a third light-emitting area EA configured to emit light with a third color, and the fourth subpixel SP4 may include a fourth light-emitting area EA configured to emit light with a fourth color.

For example, all the first to fourth light-emitting areas EA may emit light beams with different colors. For example, the first light-emitting area EA may emit green light, and the second light-emitting area EA may emit red light. The third light-emitting area EA may emit blue light, and the fourth light-emitting area EA may emit white light. However, the present specification is not necessarily limited thereto. In addition, the order in which the subpixels SP1, SP2, SP3, and SP4 are arranged may be variously changed.

With reference to FIG. 4, the first to fourth subpixels SP1, SP2, SP3, and SP4 may each include a switching transistor SW, a driving transistor DR, a capacitor Cst, a compensating circuit CC, and an organic light-emitting diode ED.

The switching transistor SW transmits a data signal to a first node N1, which is supplied through a data line DL, in response to a scan signal supplied through a gate line GL. The capacitor Cst is electrically connected to the first node N1 and charged with a voltage applied to the first node N1. The driving transistor DR may control the amount of drive current flowing to the organic light-emitting diode ED in response to a voltage applied to a gate electrode.

A semiconductor layer of the switching transistor SW or/and a semiconductor layer of the driving transistor DR may include silicon such as a-Si, poly-Si, or low-temperature poly-Si or include oxide such as indium-gallium-zinc-oxide (IGZO). The present specification is not limited thereto.

The organic light-emitting diode ED outputs light corresponding to the drive current. The organic light-emitting diode ED may output light corresponding to any one of red, green, and blue colors. The organic light-emitting diode ED may include an anode electrode, a light-emitting layer formed on the anode electrode, and a cathode electrode configured to supply a common voltage. The light-emitting layer may be implemented to emit light with the same color, such as white light, for each pixel. Alternatively, the light-emitting layer may be implemented to emit light with different colors, such as red light, green light, or blue light, for each pixel.

The compensating circuit CC may be provided in the pixel to compensate for a threshold voltage or the like of the driving transistor DR. The compensating circuit CC may include one or more transistors. The compensating circuit CC may include one or more transistors and a capacitor and be variously configured depending on a compensation method. The pixel including the compensating circuit CC may have various structures such as 3T1C, 4T2C, 5T2C, 6TIC, 6T2C, 7T1C, 7T2C, and the like.

With reference to FIG. 5, in the display device 100 according to the embodiment of the present specification, the display panel 110 may include a lower substrate 111 and an upper substrate 112 that face each other. An organic light-emitting diode ED including a transistor T, a lower electrode E1, an organic layer EL, and an upper electrode E2 may be provided between the lower substrate 111 and the upper substrate 112.

The transistor T may include an active layer ACT provided on the lower substrate 111, a first insulation film I1 provided on the active layer ACT, a gate electrode GE provided on the first insulation film I1, a second insulation film I2 provided on the gate electrode GE, and a source electrode SE and a drain electrode DE provided on the second insulation film I2 and connected to the active layer ACT through first and second contact holes CNT1 and CNT2. FIG. 5 illustrates that the transistor T is formed in a top-gate manner. However, the present specification is not limited thereto. The gate electrode GE may be formed in a bottom-gate manner and disposed below the active layer ACT.

A planarization film PLN may be provided on the transistor T and planarize a level difference caused by the transistor T and the plurality of signal lines. The planarization film PLN may be provided in the non-transmissive area NTA and may not be provided in at least a part of the transmissive area TA. The planarization film PLN may cause refraction or the like of light as the planarization film PLN transmits the light, which may degrade transparency. Therefore, in the display device 100 according to the embodiment of the present specification, the transparency of the display panel 110 may be increased by removing a part of the planarization film PLN from the transmissive area TA.

Meanwhile, FIG. 5 illustrates that the first and second insulation films I1 and I2 provided below the planarization film PLN are provided not only in the non-transmissive area NTA but also in the transmissive area TA. However, the present specification is not necessarily limited thereto. Although not illustrated, for example, in order to increase the transparency, some of the insulation films provided below the planarization film PLN may not be provided in at least a part of the transmissive area TA. For example, the second insulation film I2 may be provided in the non-transmissive area NTA and may not be provided in at least a part of the transmissive area TA.

A bank 125 and the light-emitting element ED including the lower electrode E1, the organic layer EL, and the upper electrode E2 may be provided above the planarization film PLN.

The lower electrode E1 may be provided on the planarization film PLN for each of the subpixels SP1, SP2, SP3, and SP4 and may not be provided in the transmissive area TA. The lower electrode E1 may be electrically connected to the transistor T. Specifically, the lower electrode E1 may be connected to one of the source electrode SE and the drain electrode DE of the transistor T through a third contact hole CNT3 formed through the planarization film PLN. The bank 125 may be provided between the adjacent lower electrodes E1, and the adjacent lower electrodes E1 may be electrically insulated by the bank 125.

The lower electrode E1 may be made of a metallic material with high reflectance, such as a layered structure (Ti/Al/Ti) of aluminum and titanium, a layered structure (ITO/Al/ITO) of aluminum and ITO, a layered structure (ITO/Ag alloy/ITO) of Ag alloy, Ag alloy, and ITO, and a layered structure (ITO/MoTi alloy/ITO) of MoTi alloy, MoTi alloy, and ITO. The Ag alloy may be an alloy of silver (Ag), palladium (Pd), copper (Cu), and the like. The MoTi alloy may be an alloy of molybdenum (Mo) and titanium (Ti). The lower electrode E1 may be referred to as the anode electrode.

The bank 125 may be provided on the planarization film PLN. In addition, the bank 125 may be formed to cover an edge of the lower electrode E1 and expose a part of the lower electrode E1. Therefore, the bank 125 may suppress a problem in which electric current is concentrated at an end of the lower electrode E1 and the luminous efficiency deteriorates.

The organic layer EL may be provided on the lower electrode E1. The organic layer EL may include a hole transport layer, a light-emitting layer, and an electron transport layer. In this case, when voltages are applied to the lower electrode E1 and the upper electrode E2, positive holes and electrons move to the light-emitting layer through the hole transport layer and the electron transport layer and are combined in the light-emitting layer, thereby emitting light. In the embodiment, the organic layer EL may be a common layer formed in common in the subpixels SP1, SP2, SP3, and SP4. In this case, the light-emitting layer may be a white light-emitting layer configured to emit white light. In another embodiment, the light-emitting layer of the organic layer EL may not be formed in the transmissive area TA.

The upper electrode E2 may be provided on the organic layer EL and the bank 125. The upper electrode E2 may be made of a transparent metallic material (transparent conductive material (TCO)) such as ITO and IZO capable of transmitting light, or a semi-transmissive metallic material (semi-transmissive conductive material) such as magnesium (Mg), silver (Ag), magnesium (Mg), or an alloy of silver (Ag). In case that the upper electrode E2 is made of a semi-transmissive metallic material, the light emission efficiency may be improved by a micro-cavity. The upper electrode E2 may be referred to as the cathode electrode.

An encapsulation film 140 may be provided on the light-emitting elements ED. The encapsulation film 140 may be formed on the upper electrode E2 and cover the upper electrode E2. The encapsulation film 140 serves to inhibit oxygen or moisture from penetrating into the organic layer EL and the upper electrode E2. To this end, the encapsulation film 140 may include at least one inorganic film and at least one organic film.

A color filter CF may be provided on one surface of the upper substrate 112 that faces the lower substrate 111. The color filter CF may be patterned for each of the subpixels SP1, SP2, SP3, and SP4.

Specifically, the color filters CF may include a first color filter, a second color filter, a third color filter, and a fourth color filter. For example, the first color filter may be a green color filter disposed to correspond to the light-emitting area EA of the first subpixel SP1 and configured to transmit green light. The second color filter may be a red color filter disposed to correspond to the light-emitting area EA of the second subpixel SP2 and configured to transmit red light. The third color filter CF3 may be a blue color filter disposed to correspond to the light-emitting area EA of the third subpixel SP3 and configured to transmit blue light. The fourth color filter may be a white color filter disposed to correspond to the light-emitting area EA4 of the fourth subpixel SP4 and configured to transmit white light. The white color filter may be made of a transparent organic material that transmits white light. However, the present specification is not necessarily limited thereto.

A black matrix BM may be provided between the color filters CF. The black matrix BM may be provided between the subpixels SP1, SP2, SP3, and SP4 and suppress the occurrence of a color mixture between the adjacent subpixels SP1, SP2, SP3, and SP4. In addition, the black matrix BM may inhibit the light, which enters from the outside, from being reflected by the plurality of signal lines provided between the subpixels SP1, SP2, SP3, and SP4.

In addition, the black matrix BM may be provided between the transmissive area TA and the plurality of subpixels SP1, SP2, SP3, and SP4 and inhibit the light emitted from the plurality of subpixels SP1, SP2, SP3, and SP4 from propagating to the transmissive area TA. In the embodiment, the black matrix BM may not be provided between the white subpixel and the transmissive area TA. In the display panel 110 of the display device 100 according to the embodiment of the present specification, the black matrix BM is not provided between the white subpixel and the transmissive area TA, which may reduce an area for forming the black matrix BM. Therefore, in the display device 100 according to the embodiment of the present specification, the transmittance of the display panel 110 may be improved. The black matrix BM may include a material that absorbs light, for example, a black dye that absorbs all the light beams in a visible wavelength band.

The color filter CF and the black matrix BM are not provided in the transmissive area TA to maintain high light transmittance in the transmissive area TA.

The lower substrate 111 may be a silicon wafer substrate formed by using a plastic film, a glass substrate, or a semiconductor process. The upper substrate 112 may be a plastic film, a glass substrate, or an encapsulation film. The upper substrate 112 and the lower substrate 111 may each be made of a transparent material. The lower substrate 111 may be formed to be larger than the upper substrate 112. Therefore, a part of the lower substrate 111 may be exposed without being covered by the upper substrate 112.

As described above, the display device 100 according to the embodiment of the present specification includes the transmissive area TA configured to transmit the incident light almost in an intact manner, and the light-emitting area EA configured to emit light. As a result, in the display device according to the embodiment of the present specification, an object or background positioned on the rear or front surface of the display device 100 may be visible through the transmissive areas TA of the display device 100.

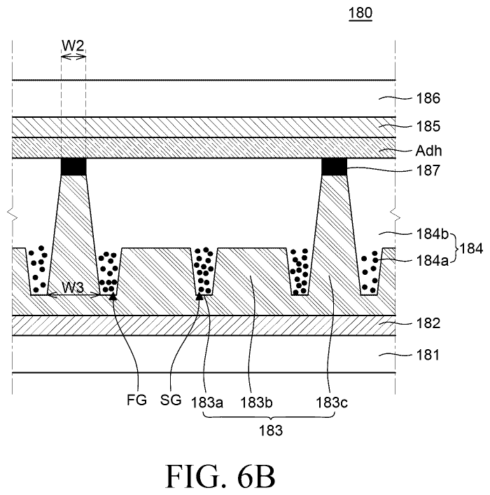

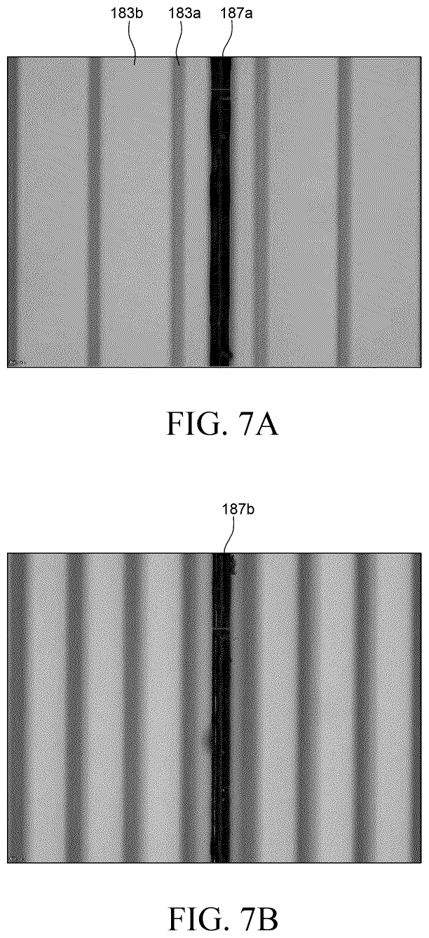

Hereinafter, the light control panel 180 will be described more specifically with reference to FIG. 6A.

FIG. 6A is a cross-sectional view illustrating the light control panel according to the embodiment of the present specification.

With reference to FIG. 1, FIG. 6A, in the display device 100 according to the embodiment of the present specification, the light control panel 180 may be implemented in the transmissive mode that transmits the incident light, and the light-blocking mode that blocks the incident light. It may be assumed that in the display device 100 according to the embodiment of the present specification, the light-blocking mode refers to a case in which the light transmittance of the light control panel 180 is lower than α%, and the transmissive mode refers to a case in which the light transmittance of the light control panel 180 is equal to or lower than β%. In this case, α may be a value smaller than β. For example, α may be less than 10%, particularly less than 1%. The light transmittance of the light control panel 180 refers to a ratio of the light outputted from the light control panel 180 to the light entering the light control panel 180.

To this end, as illustrated in FIG. 6A, the light control panel 180 of the display device 100 according to the embodiment of the present specification includes a first substrate 181, a first electrode 182, a dielectric layer 183, an ink layer 184, a bonding layer Adh, a second electrode 185, and a second substrate 186.

The first substrate 181 and the second substrate 186 may each be a glass substrate or a plastic film. However, the present specification is not limited thereto.

The first electrode 182 may be disposed on the first substrate 181.

The second electrode 185 may be disposed on one surface of the second substrate 186 that faces the first substrate 181. As shown, the first electrode 182 and the second electrode 185 are spaced apart from each other.

The first electrode 182 and the second electrode 185 may each be made of a

transparent conductive material. For example, the first electrode 182 and the second electrode 185 may each be made of a transparent conductive material such as tin oxide (TO), indium tin oxide (ITO), indium zinc oxide (IZO), and indium tin zinc oxide (ITZO). However, the present specification is not limited thereto.

The dielectric layer 183 may be disposed between the first electrode 182 and the second electrode 185. The dielectric layer 183 may be made of a transparent material and transmits light. However, the present specification is not limited thereto. For example, the dielectric layer 183 may be made of transparent resin. The transparent resin may be acrylic resin. However, the present specification is not limited thereto.

The dielectric layer 183 includes a plurality of grooves 183a, a plurality of dielectric patterns 183b, and a plurality of spacers 183c. In some embodiments, the plurality of dielectric patterns 183b and the plurality of spacers 183c are integrally formed such that the plurality of dielectric patterns 183b and the plurality of spacers 183c are made of the same material. Further, because the plurality of dielectric patterns 183b and the plurality of spacers 183c are integrally formed, the plurality of dielectric patterns 183b and the plurality of spacers 183c are single, unified piece rather than being assembled from multiple separate components.

The plurality of grooves 183a may extend in a first direction and be spaced apart from one another at predetermined intervals in a second direction intersecting the first direction. For example, the grooves 183a may be formed in a direction perpendicular to the direction in which the pixels P are disposed on the display panel 110 disposed above the light control panel 180. The grooves 183a may be disposed to overlap both the non-transmissive area NTA and the transmissive area TA.

The plurality of dielectric patterns 183b is disposed between the plurality of grooves 183a. The plurality of dielectric patterns 183b may be formed in a direction identical to an extension direction of the plurality of grooves 183a and disposed to overlap both the non-transmissive area NTA and the transmissive area TA.

The plurality of spacers 183c is spaced apart from each other. Further, the plurality of spacers 183c is disposed to be spaced apart from the plurality of dielectric patterns 183b and further protrudes toward the second electrode 185 than the plurality of dielectric patterns 183b. For example, the plurality of spacers 183c may be disposed between the plurality of dielectric patterns 183b disposed adjacent to one another in a plan view. The plurality of grooves 183a may be disposed on at least one side of the plurality of spacers 183c. For example, the plurality of spacers 183c may be disposed to be spaced apart from the plurality of dielectric patterns 183b with the plurality of grooves 183a interposed therebetween. For example, the plurality of spacers 183c may be formed in the direction identical to the extension direction of the plurality of grooves 183a and disposed to overlap both the non-transmissive area NTA and the transmissive area TA.

Referring to FIG. 6A, a spacer of the plurality of spacers 183c has a height D1 that is defined between the top surface 183cTS of the spacer 183c and a top surface 182TS of the first electrode 182. A dielectric pattern of the plurality of dielectric patterns 183b has a height D2 that is defined between the top surface 183bTS of the dielectric pattern 183b and the top surface 182TS of the first electrode 182. The spacer 183c protrudes from the first electrode 182 towards the second electrode 185 more than the dielectric pattern 183b. Therefore, in some embodiments, the height D1 is greater than the height D2.

For convenience of description, FIG. 6A illustrates that the plurality of grooves 183a and the two dielectric patterns 183b are disposed between the two spacers 183c of the dielectric layer 183. However, the present specification is not limited thereto. In the dielectric layer 183, three or more dielectric patterns 183b may be disposed between the two spacers 183c. In addition, in the dielectric layer 183, the above-mentioned structures may be continuously disposed. That is, in the dielectric layer 183, the plurality of grooves 183a and the plurality of dielectric patterns 183b disposed between the two spacers 183c may be disposed continuously.

Referring to FIGS. 6A and 6B, a first groove FG of the plurality of grooves 183a is disposed between the spacer 183c and the dielectric pattern 183b, and a second groove SG plurality of grooves 183a is disposed between adjacent dielectric patterns of the plurality of dielectric patterns 183b.

The plurality of spacers 183c may maintain a constant interval between the first substrate 181 and the second substrate 186. That is, the interval between the first substrate 181 and the second substrate 186 may be determined by heights of the plurality of spacers 183c.

In some embodiments, top surfaces of the plurality of dielectric patterns 183b and the plurality of spacers 183c may be flat surfaces. For example, in case that top surfaces of the plurality of dielectric patterns and the plurality of spacers are convex, phase separation may occur because of total reflection due to differences in refractive indexes between the plurality of dielectric patterns, the plurality of spacers, and a solvent of the ink layer. In the embodiment of the present specification, the top surfaces of the plurality of dielectric patterns 183b and the plurality of spacers 183c are flat surfaces, such that total reflection does not occur on the top surfaces of the plurality of dielectric patterns 183b and the plurality of spacers 183c, which may improve the image quality.

The plurality of dielectric patterns 183b and the plurality of spacers 183c may each have a trapezoidal shape in which a bottom surface has a larger width than a top surface. For example, the plurality of dielectric patterns 183b and the plurality of spacers 183c may each have the trapezoidal shape in which the bottom surface, which adjoins the first electrode 182, has a larger width than the top surface that adjoins the second electrode 185. Referring to FIG. 6A, a dielectric pattern 183b has a bottom width W4 that is greater than a top width W5. However, the present specification is not limited thereto. The plurality of dielectric patterns 183b and the plurality of spacers 183c may each have a square, rectangular, or triangular cross-sectional shape.

Meanwhile, the plurality of dielectric patterns 183b and the plurality of spacers 183c may be integrated. That is, the plurality of dielectric patterns 183b and the plurality of spacers 183c included in the dielectric layer 183 may be integrated and made of the same material. For example, the plurality of dielectric patterns 183b and the plurality of spacers 183c may be integrated by an imprinting process or a photolithography process.

For example, the plurality of grooves 183a, the plurality of dielectric patterns 183b, and the plurality of spacers 183c may be simultaneously formed by an imprinting process. Therefore, the process may be simplified, the process costs may be reduced, and the process time may be shortened, such that the process may be optimized, and the production energy may be reduced. In addition, as the process of the display device 100 according to the embodiment of the present specification is optimized, the occurrence of greenhouse gas, which may be generated by the manufacturing process, may be reduced, thereby implementing ESG (environment/social/governance).

For example, in case that the plurality of dielectric patterns 183b and the plurality of spacers 183c are formed by the imprinting process, the plurality of dielectric patterns 183b and the plurality of spacers 183c may each have a trapezoidal shape in which a bottom surface has a larger width than a top surface. In this embodiment, each spacer of the plurality of spacers 183c has a trapezoidal cross-section such that a bottom width W3 of the trapezoidal cross-section of the spacer is greater than a top width W2 of the trapezoidal cross-section of the spacer. Here, a width of the light-blocking pattern 187 is equal to or greater than the top width W2 of the trapezoidal cross-section of the spacer. In addition, each dielectric pattern of the plurality of dielectric patterns 183b has a trapezoidal cross-section such that a bottom width W4 of the trapezoidal cross-section of the dielectric pattern is greater than a top width W5 of the trapezoidal cross-section of the dielectric pattern.

For example, in case that the plurality of dielectric patterns 183b and the plurality of spacers 183c are formed by the photolithography process, the plurality of dielectric patterns 183b and the plurality of spacers 183c may each have a rectangular or square shape in which a width of a bottom surface and a width of a top surface are equal to each other.

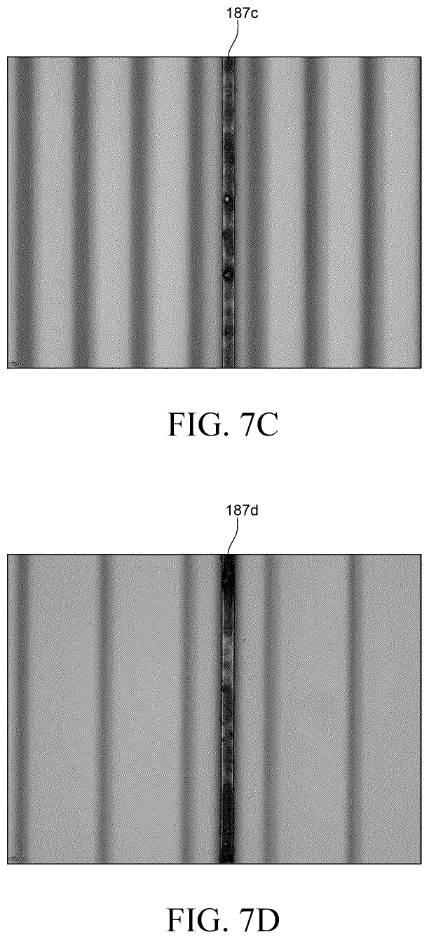

The display device 100 according to the embodiment of the present specification may include a light-blocking pattern 187 disposed on the top surfaces of the plurality of spacers 183c. For example, the light-blocking pattern 187 may be made of a black-based material. For example, the light-blocking pattern 187 may be black-based materials dispersed in a solvent. For example, the light-blocking pattern 187 may be black resin or black ink. However, the present specification is not limited thereto. For example, printing uniformity of the light-blocking pattern 187 may be improved by adjusting ratios and thicknesses of the solvent and the black-based materials. This configuration will be described below with reference to FIGS. 7A to 7D.

The top surfaces 183cTS of the plurality of spacers 183c may be coated with the light-blocking pattern 187. Specifically, the top surfaces 183cTS of the plurality of spacers 183c, which overlap the transmissive area TA and the non-transmissive area NTA of the display panel 110, are coated with the black-based material, which may inhibit the light from passing through the plurality of spacers 183c.

In this case, a width of the light-blocking pattern 187 may be smaller than a first width W1 between the top surfaces 183bTS of the plurality of dielectric patterns 183b, equal to or larger than a minimum width of the plurality of spacers 183c, i.e., a second width W2 of the top surface 183cTS of each of the plurality of spacers 183c, particularly, larger than the second width W2 of the top surface 183cTS of each of the plurality of spacers 183c.

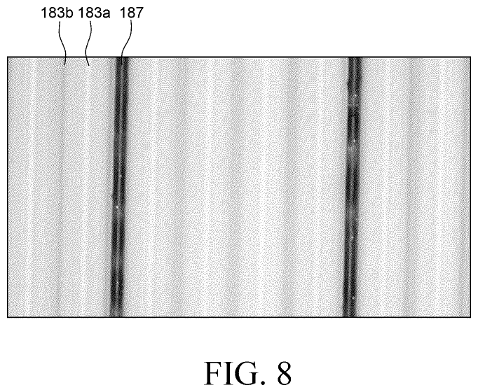

For example, in case that the width of the light-blocking pattern 187 has a value between the first width W1 between the top surfaces of the plurality of dielectric patterns 183b and the second width W2 of the top surface of each of the plurality of spacers 183c, the light-blocking pattern 187 may be uniformly formed on the front surface of the plurality of spacers 183c while having straightness, which may improve printing width uniformity. This configuration will be described below with reference to FIG. 8.

The light-blocking pattern 187 may be formed by coating the top surfaces of the plurality of spacers 183c with the black-based material by a gravure or transfer method and curing the black-based material. However, the present specification is not limited thereto. For example, in case that the gravure method is applied, a large area may be printed. For example, in case that a large area may be printed, the process costs may be reduced, and the process time may be shortened, such that the process may be optimized, and the production energy may be reduced. In addition, as the process of the display device 100 according to the embodiment of the present specification is optimized, the occurrence of greenhouse gas, which may be generated by the manufacturing process, may be reduced, thereby implementing ESG (environment/social/governance).

In the display device 100 according to the embodiment of the present specification, the light control panel 180 may include the ink layer 184 disposed in the space between the dielectric layer 183 and the second electrode 185. Specifically, the ink layer 184 may be disposed in the space between the plurality of grooves 183a, the plurality of dielectric patterns 183b, and the second electrode 185. However, the present specification is not limited thereto. For example, the ink layer 184 may not be disposed between the plurality of spacers 183c and the second electrode 185.

In the display device 100 according to the embodiment of the present specification, the ink layer 184 may include a plurality of charged particles 184a provided in a solvent 184b. Specifically, the plurality of charged particles 184a may be electrified as either negative electric charges or positive electric charges, distributed in the solvent 184b, and configured to block the light entering from the outside. For example, the solvent 184b may be a transparent organic solvent. In addition, for example, the plurality of charged particles 184a may be electrophoresis materials, for example, include black ink including carbon black. However, the present specification is not limited thereto.

In the display device 100 according to the embodiment of the present specification, the bonding layer Adh is disposed between the second electrode 185 and the plurality of spacers 183c coated with the ink layer 184 and the light-blocking pattern 187. For example, the bonding layer Adh may be a transparent bonding film, such as an optically clear adhesive (OCA), or a transparent bonding agent such as optically clear resin (OCR).

In the display device 100 according to the embodiment of the present specification, the light control panel 180 is disposed outside the display panel 110 and provided separately from the display panel 110, as illustrated in FIG. 1. In this case, the light control panel 180 may be formed in a film shape and disposed on one surface of the display panel 110 by a separate bonding layer. However, the present specification is not limited thereto.

Although not illustrated, for example, the light control panel 180 may be disposed in the display panel 110. In this case, the light control panel 180 may be disposed between the lower substrate 111 and the upper substrate 112 of the display panel 110. In this case, the first substrate 181 and the second substrate 186 of the light control panel 180 may be excluded. However, the present specification is not limited thereto.

In a light control panel in the related art, no ink layer is positioned above a plurality of spacers that adjoins a bonding layer. The plurality of spacers is disposed to overlap the transmissive area TA and the non-transmissive area NTA of the display panel. When the light-blocking mode of the display device is implemented, the light passes through the top surfaces of the plurality of spacers, particularly the top surfaces of the plurality of spacers overlapping the transmissive area TA, which causes a problem in that the plurality of spacers is visually recognized, and the shield factor decreases.

Therefore, in the display device 100 according to the embodiment of the present specification, the light-blocking pattern 187 is disposed above the plurality of spacers 183c and inhibits light from passing through the top surfaces of the plurality of spacers 183c when the light-blocking mode is implemented, such that the plurality of spacers 183c is inhibited from being visually recognized in the transmissive area TA of the display panel 110, thereby improving the shield factor.

Hereinafter, a method of implementing the transmissive mode and the light-blocking mode on the basis of whether a voltage is applied will be described in detail with reference to the drawings.

FIG. 6A is a cross-sectional view for explaining a method of implementing the light-blocking mode in the light control panel according to the embodiment of the present specification. FIG. 6B is a cross-sectional view for explaining a method of implementing the transmissive mode in the light control panel according to the embodiment of the present specification.

As illustrated in FIG. 6A, in a state in which no voltage is applied to the first electrode 182 and the second electrode 185, the plurality of charged particles 184a is uniformly distributed and disposed in the ink layer 184. For instance, some portions of the plurality of charged particles 184a may be present in the first groove FG and the second SG. The other portions of the plurality of charged particles 184a may be dispersed in the ink layer 184. Therefore, the light from the outside is blocked by the plurality of charged particles 184a disposed uniformly, such that the light-blocking mode for blocking light may be implemented. The external light cannot pass through the light control panel 180.

In addition, in the display device 100 according to the embodiment of the present specification, the light-blocking pattern 187 is disposed on the top surfaces of the plurality of spacers 183c of the light control panel 180, such that the process of blocking light may be further improved when the light-blocking mode is implemented.

When a voltage is applied to the first electrode 182 and the second electrode 185, the dielectric materials of the plurality of dielectric patterns 183b are dielectrically polarized, and a dielectric polarization density may vary depending on the shape of the top surface of the dielectric layer 183. Therefore, the electric field may be formed most intensively in the plurality of grooves 183a. For instance, when a voltage is applied between the first electrode 182 and the second electrode 185, most of the plurality of charged particles may be disposed within the first groove FG and the second groove SG as shown in FIG. 6B.

The plurality of charged particles 184a is moved by the electric field generated between the first electrode 182 and the second electrode 185, such that the plurality of charged particles 184a may be moved to the plurality of grooves 183a by the electric field when the voltage is applied to the first electrode 182 and the second electrode 185. Therefore, as illustrated in FIG. 6B, when a voltage is applied to the first electrode 182 and the second electrode 185, the plurality of charged particles 184a is positioned only in the plurality of grooves 183a, such that the plurality of charged particles 184a may not be disposed in the area that overlaps the plurality of dielectric patterns 183b, and high light transmittance may be implemented. Therefore, when a voltage is applied to the first electrode 182 and the second electrode 185, the area in which the plurality of dielectric patterns 183b is disposed may transmit external light, such that the light having passed through the light control panel 180 may enter the display panel 110.

As described above, the external light may pass through the display device 100 through the area, in which the plurality of dielectric patterns 183b of the light control panel 180 is formed, and the transmissive area TA of the display panel 110. In the display device 100 according to the embodiment of the present specification, the plurality of dielectric patterns 183b of the light control panel 180 may be disposed to overlap the transmissive area TA of the display panel 110 to implement high light transmittance in the transmissive mode.

Hereinafter, the effect according to the embodiment of the present disclosure described above will be described in more detail with reference to various examples.

FIGS. 7A to 7D is an image illustrating a printed state of the light-blocking pattern of the light control panel according to the embodiment of the present specification.

First, FIG. 7A illustrates Example 1 in which the light-blocking pattern 187a is coated with black ink including a solvent and a black-based material in a ratio of 4:6 with a thickness of 26 bar, FIG. 7B illustrates Example 2 in which the light-blocking pattern 187b is coated with black ink including a solvent and a black-based material in a ratio of 3:7 with a thickness of 26 bar, FIG. 7C illustrates Example 3 in which the light-blocking pattern 187c is coated with black ink including a solvent and a black-based material in ratio of 4:6 with a thickness of 18 bar, and FIG. 7D illustrates Example 4 in which the light-blocking pattern 187d is coated with black ink including a solvent and a black-based material in ratio of 3:7 with a thickness of 18 bar.

With reference to FIGS. 7A to 7D, it can be seen that a printed state of the light-blocking pattern 187a in Example 1 illustrated in FIG. 7A is best. It can be seen that in case that the thicknesses of the light-blocking patterns 187c and 187d are decreased as in Examples 3 and 4 illustrated in FIGS. 7C and 7D, the light-blocking patterns 187c and 187d are disconnected in the middle thereof. In addition, it can be seen that in case that the proportion of the solvent is low when the light-blocking pattern 187b is formed as in Example 2 illustrated in FIG. 7B, the black-based materials are agglomerated. The printing uniformity of the light-blocking pattern 187a may be improved by optimizing the ratio and thicknesses of the solvent and the black-based material, like the light-blocking pattern 187a in Example 1 illustrated in FIG. 7A.

Hereinafter, the light-blocking pattern 187 of the light control panel, which is coated with black ink including a solvent and a black-based material in a ratio of 4:6 with a thickness of 26 bar as in Example 1, will be described as an example.

FIG. 8 is an image illustrating printing width uniformity of the light-blocking pattern of the light control panel according to the embodiment of the present specification.

The width of the light-blocking pattern 187 was configured to have a value between the first width w1 between the top surfaces of the plurality of dielectric patterns 183b and the minimum width of the spacer 183c, i.e., the second width w2 of the top surface of the spacer 183c. For example, the first width w1 between the top surfaces of the plurality of dielectric patterns 183b was set to 40.0 μm, and the second width w2, i.e., the minimum width of the top surface of the spacer 183c was set to 19.0 μm. In this case, the width of the light-blocking pattern 187 was set to 20 μm, and the printed state was identified.

As illustrated in FIG. 8, in case that the width of the light-blocking pattern 187 is set to the value between the first width w1 between the top surfaces of the plurality of dielectric patterns 183b and the second width w2, i.e., the minimum width of the spacer 183c, the light-blocking pattern 187 may be uniformly formed while having straightness, which may improve the printing width uniformity of the light-blocking pattern 187.

Hereinafter, the effect according to the embodiment of the present disclosure described above will be described in more detail with reference to Example and Comparative Example.

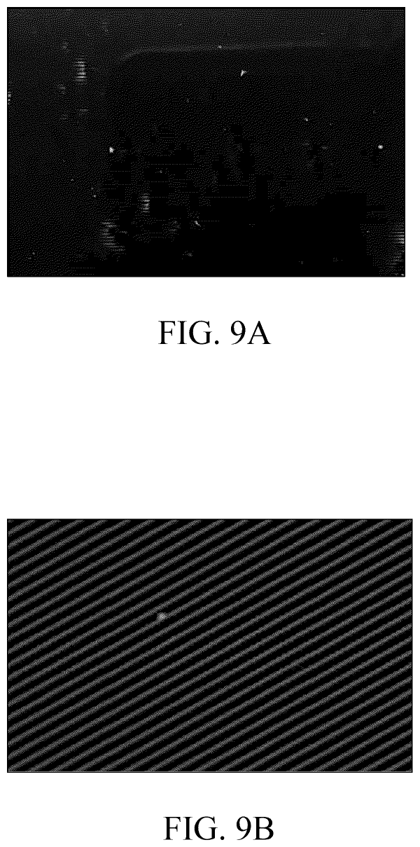

FIGS. 9A and 9B are front-of-screen (FOS) images illustrating external appearance states in the light-blocking modes of the display devices according to the embodiment of the present specification and a comparative example.

The FOS may be a qualitative indicator defined as a degree of uniformity of a screen perceived by a viewer when the viewer watches images on the screen of the display device.

First, Table 1 below and FIG. 9A show the display device 100 according to the embodiment of the present specification.

In addition, the comparative example shown in Table 1 below and FIG. 9B has a structure in which no light-blocking pattern is disposed on the top surfaces of the plurality of spacers 183c, in comparison with the example.

FOS images in the light-blocking mode were captured after the display devices of the example and the comparative example were manufactured. In this case, the transmittance in the light-blocking mode is shown in Table 1 below.

TABLE 1

| | Example | Comparative Example |
|---|---|---|
| Transmittance (%) | 0.6 | 4.71 |

As shown in Table 1 and FIGS. 9A and 9B, it can be seen that in the display device 100 of the example, light from the outside is blocked in the light-blocking mode, and the external light cannot pass through the light control panel 180, such that the transmittance in the light-blocking mode decreases. In particular, it can be seen that in the display device 100 of the example, the light-blocking pattern 187 is disposed on the top surfaces of the plurality of spacers 183c of the light control panel 180, such that the process of blocking light may be further improved when the light-blocking mode is implemented, and the transmittance remarkably decreases in comparison with the display device of the comparative example.

The exemplary embodiments of the present disclosure can also be described as follows:

According to an aspect of the present disclosure, a light control panel includes a first electrode, a second electrode disposed on the first electrode while facing the first electrode, a dielectric layer provided between the first electrode and the second electrode and comprising a plurality of dielectric patterns disposed between a plurality of grooves, and a plurality of spacers spaced apart from the plurality of dielectric patterns and further protruding toward the second electrode than the plurality of dielectric patterns, an ink layer disposed in a space between the dielectric layer and the second electrode and comprising charged particles, a light-blocking pattern disposed on the plurality of spacers, and a bonding layer disposed between the ink layer and the second electrode, the light-blocking pattern is disposed to be in contact with the bonding layer.

The plurality of dielectric patterns and the plurality of spacers each may include a transparent material and have a rectangular shape, a square shape, or a trapezoidal shape in which a bottom surface may have a larger width than a top surface.

The plurality of spacers extends in a first direction, and the plurality of grooves may extend in the same direction as the plurality of spacers.

The plurality of dielectric patterns and the plurality of spacers may be integrally disposed.

The first electrode and the second electrode may be made of a transparent conductive material.

A width of the light-blocking pattern may be equal to or larger than a width of a top surface of each of the plurality of spacers and smaller than a width between the plurality of dielectric patterns.

The light-blocking pattern may be made of a black-based material.

According to another aspect of the present disclosure, a display device including a transparent display panel comprising a transmissive area configured to transmit external light, and a non-transmissive area in which a plurality of pixels is disposed, and a light control panel positioned below the display panel, the light control panel includes a first electrode, a second electrode disposed on the first electrode while facing the first electrode, a dielectric layer provided between the first electrode and the second electrode and comprising a plurality of dielectric patterns disposed between a plurality of grooves, and a plurality of spacers spaced apart from the plurality of dielectric patterns and further protruding toward the second electrode than the plurality of dielectric patterns, an ink layer disposed in a space between the dielectric layer and the second electrode and comprising charged particles, a light-blocking pattern disposed on the plurality of spacers, and a bonding layer disposed between the ink layer and the second electrode, and the light-blocking pattern is disposed to be in contact with the bonding layer.

The plurality of dielectric patterns and the plurality of spacers each may include a transparent material and have a rectangular shape, a square shape, or a trapezoidal shape in which a bottom surface may have a larger width than a top surface.

The plurality of spacers extends in a first direction, and the plurality of grooves may extend in the same direction as the plurality of spacers.

The plurality of dielectric patterns and the plurality of spacers may be integrally disposed.

The first electrode and the second electrode may be made of a transparent conductive material.

A width of the light-blocking pattern may be larger than a width of a top surface of each of the plurality of spacers and smaller than a width between the plurality of dielectric patterns.

The light-blocking pattern may be made of a black-based material.

The charged particles may be positioned between the plurality of grooves when a voltage is applied between the first electrode and the second electrode.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. The protective scope of the present disclosure should be construed based on the following claims, and all the technical concepts in the equivalent scope thereof should be construed as falling within the scope of the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A light control panel, comprising:
a first electrode;
a second electrode on the first electrode;
a dielectric layer between the first electrode and the second electrode, the dielectric layer including:
a plurality of dielectric patterns disposed between a plurality of grooves, and
a plurality of spacers spaced apart from the plurality of dielectric patterns, the plurality of spacers further protruding toward the second electrode than the plurality of dielectric patterns;
an ink layer disposed in a space between the dielectric layer and the second electrode, the ink layer including charged particles;
a light-blocking pattern disposed on the plurality of spacers; and
a bonding layer disposed between the ink layer and the second electrode,
wherein the light-blocking pattern is in contact with the bonding layer.

2. The light control panel of claim 1, wherein the plurality of dielectric patterns and the plurality of spacers each include a transparent material and have a rectangular shape, a square shape, or a trapezoidal shape in which a bottom surface has a larger width than a top surface.

3. The light control panel of claim 1, wherein the plurality of spacers extends in a first direction, and the plurality of grooves extends in the same direction as the plurality of spacers.

4. The light control panel of claim 1, wherein the plurality of dielectric patterns and the plurality of spacers are integrally disposed.

5. The light control panel of claim 1, wherein the first electrode and the second electrode are made of a transparent conductive material.

6. The light control panel of claim 1, wherein a width of the light-blocking pattern is equal to or larger than a width of a top surface of each of the plurality of spacers and smaller than a width between the plurality of dielectric patterns.

7. The light control panel of claim 1, wherein the light-blocking pattern is made of a black-based material.

8. A display device, comprising:
a transparent display panel having a transmissive area configured to transmit external light, and a non-transmissive area in which a plurality of pixels is disposed; and
a light control panel adjacent to the transparent display panel,
wherein the light control panel includes:
a first electrode;
a second electrode on the first electrode and facing the first electrode;
a dielectric layer provided between the first electrode and the second electrode, the dielectric layer including:
a plurality of dielectric patterns disposed between a plurality of grooves, and
a plurality of spacers spaced apart from the plurality of dielectric patterns and further protruding toward the second electrode than the plurality of dielectric patterns;
an ink layer disposed in a space between the dielectric layer and the second electrode, the ink layer including charged particles;
a light-blocking pattern on the plurality of spacers; and
a bonding layer between the ink layer and the second electrode, and
wherein the light-blocking pattern is in contact with the bonding layer.

9. The display device of claim 8, wherein the plurality of dielectric patterns and the plurality of spacers each include a transparent material and have a rectangular shape, a square shape, or a trapezoidal shape in which a bottom surface has a larger width than a top surface.

10. The display device of claim 8, wherein the plurality of spacers extends in a first direction, and the plurality of grooves extends in the same direction as the plurality of spacers.

11. The display device of claim 8, wherein the plurality of dielectric patterns and the plurality of spacers are integrally disposed.

12. The display device of claim 8, wherein the first electrode and the second electrode are made of a transparent conductive material.

13. The display device of claim 8, wherein a width of the light-blocking pattern is larger than a width of a top surface of each of the plurality of spacers and smaller than a width between the plurality of dielectric patterns.

14. The display device of claim 13, wherein the light-blocking pattern is made of a black-based material.

15. The display device of claim 8, wherein the charged particles are positioned between the plurality of grooves when a voltage is applied between the first electrode and the second electrode.

16. A transparent display device, comprising:
a transparent display panel including a transmissive area configured to transmit external light and a non-transmissive area in which a plurality of pixels is disposed; and
a light control panel coupled to the transparent display panel, the light control panel including:
a first electrode facing and spaced apart from a second electrode;
a plurality of spacers between the first electrode and the second electrode, the plurality of spacers being spaced apart from each other, each spacer of the plurality of spacers having a top surface; and
a light-blocking pattern on the top surface of the plurality of spacers, the light-blocking pattern being spaced apart from the second electrode.

17. The transparent display device of claim 16, further comprising:
a plurality of dielectric patterns between adjacent spacers of the plurality of spacers, the plurality of dielectric patterns being spaced apart from each other,
each dielectric pattern of the plurality of dielectric patterns having a top surface,
wherein the first electrode has a top surface,
wherein a first distance between the top surface of the first electrode and the top surface of a dielectric pattern of the plurality of dielectric patterns is smaller than a second distance between the top surface of the first electrode and the top surface of a spacer of the plurality of spacers.

18. The transparent display device of claim 17, further comprising:
a first groove between the spacer and the dielectric pattern; and
a second groove between adjacent dielectric patterns of the plurality of dielectric patterns.

19. The transparent display device of claim 17, further comprising:
a plurality of charged particles between the first electrode and the second electrode,
wherein some portions of the plurality of charged particles are present in the first groove and the second groove.

20. The transparent display device of claim 17, further comprising:
a plurality of charged particles between the first electrode and the second electrode,
wherein, in operation, when a voltage is applied between the first electrode and the second electrode, the plurality of charged particles are disposed within the first groove and the second groove.

21. The transparent display device of claim 17, wherein the plurality of spacers and the plurality of dielectric patterns are integrally formed and are made of a same material.
